(19) United States
(12) Patent Application Publication
(10) Pub. No.: US 2026/0029725 A1
(43) Pub. Date: Jan. 29, 2026

(54) LOCALIZED REGION OF INTEREST BASED IMAGE GRABS FOR IMPROVED METROLOGY COST OF OWNERSHIP

(71) Applicant: KLA Corporation, Milpitas, CA (US)

(72) Inventors: Monica Ravikumar, Chennai (IN); Vijay Pormannan, Salem (IN); Thirupurasundari Jayaraman, Chennai (IN); Hari Pathangi Sriraman, Chennai (IN)

(21) Appl. No.: 19/265,551

(22) Filed: Jul. 10, 2025

Related U.S. Application Data
(60) Provisional application No. 63/693,219, filed on Sep. 11, 2024.

(30) Foreign Application Priority Data
Jul. 29, 2024 (IN) 202441057516

(51) Int. Cl. G03F 7/00; G06V 10/25

(52) U.S. Cl. CPC G03F 7/706831; G03F 7/70475; G06V 10/25

(57) ABSTRACT

Systems and methods provide for localizing a beam to a plurality of regions of interest for creating a synthetically stitched image. The process includes creating at least a first region of interest of a target and at least a second region of interest of the target, each of the first region of the target and the second region of interest defined by one or more previously established rules for polygonal dimensions. Next, performing a first scan of the target to capture at least one first image of the first region of interest and performing a second scan of the target to capture at least one second image of the second region of interest occurs. The captured images are then stitched together to create a stitched final image of the target.

### CROSS-REFERENCE TO OTHER APPLICATIONS

The present application claims priority to India Provisional Patent Application No. 202441057516, filed Jul. 29, 2024, and U.S. Provisional Patent Application No. 63/693,219, filed Sep. 11, 2024, entitled, Localized RoI Based Image Grabs for Improved Metrology Cost of Ownership, both of which are incorporated by reference in the entirety

### TECHNICAL FIELD

The present invention generally relates to improvement of Move Acquire Measure (MAM) times during electron scanning, and more particularly, to a system and method for focusing the electron scan to a plurality of regions of interest on a target and stitching the plurality of images to create a synthetically stitched final image.

### BACKGROUND

Inline metrology tools are used in semiconductor fabs to measure overlay or Critical Dimension (CD) errors. These tools have traditionally been using photo optical images to detect these errors. However, these tools often suffer from precision and tool induced errors. There are also limitations on scanning target designs based on the target's size and geometry. Electron beam (eBeam) based solutions are an alternative to obtain improved accuracy and to scan smaller targets or on-device patterns.

In an eBeam metrology tool, the target image is grabbed by deflecting the eBeam from one pixel to the other to raster the entire image and the emitted electrons are captured using detectors and converted to a grayscale image.

Currently, eBeam metrology tools scan the entire field of view (FoV), in which the target of interest used to calculate metrology values constitutes only a relatively small portion of the FoV. Specifically, within the target area, only the Region of Interest (RoI) containing the edge of interest to be measured is used by algorithms to calculate the final metrology values. Current systems contain inherent inefficiencies including the total time allotment and electrons spent imagining that are outside of the target area that is not used in calculating final metrology values. Furthermore, current RoI creation requires manual user inputs, leading to user variability and error sources.

As such, it would be advantageous to provide a system and method to improve the electron beam inspection problems identified above.

### SUMMARY

In some aspects, the techniques described herein relate to a system for focusing one or more illumination beams to one or more regions of interest including: a controller including one or more processors configured to execute program instructions stored in a memory device, wherein the program instructions are configured to cause the one or more processors to focus an illumination beam to a region of interest by: creating at least a first region of interest of a target and at least a second region of interest of the target, each of the first region of the target and the second region of interest defined by one or more previously established rules for polygonal dimensions; performing a first scan of the target to capture at least one first image of the first region of interest; performing a second scan of the target to capture at least one second image of the second region of interest; and stitching the at least one first image and the at least one second image to create a stitched image of the target.

In some aspects, the techniques described herein relate to a system for focusing an electron beam during inspection of a substrate, the system including: an illumination source configured to generate one or more illumination beams; a set of optical elements configured to direct the one or more illumination beams from the illumination source to a surface of a substrate; and one or more controllers including one or more processors configured to execute program instructions causing the one or more processors to: a controller including one or more processors configured to execute program instructions stored in a memory device, wherein the program instructions are configured to cause the one or more processors to focus an electron scan to a region of interest by: creating at least a first region of interest of a target and at least a second region of interest of the target, each of the first region of the target and the second region of interest defined by one or more previously established rules for polygonal dimensions; performing a first scan of the target to capture at least one first image of the first region of interest; performing a second scan of the target to capture at least one second image of the second region of interest; stitching the at least one first image and the at least one second image to create a stitched image of the target; calculating at least one metrology value of the target based at least in part on the stitched image of the target.

In some aspects, the techniques described herein relate to a method for focusing one or more illumination beams to one or more regions of interest on a target including: creating at least a first region of interest of a target and at least a second region of interest of the target, each of the first region of the target and the second region of interest defined by one or more previously established rules for polygonal dimensions; performing a first scan of the target to capture at least one first image of the first region of interest; performing a second scan of the target to capture at least one second image of the second region of interest; stitching the at least one first image and the at least one second image to create a stitched image of the target; calculating at least one metrology value of the target based at least in part on the stitched image of the target.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1 illustrates a block diagram of a metrology system, in accordance with one or more embodiments of the present disclosure.

FIG. 2A illustrates an exemplary image of a field of view taken of a target location using conventional SEM imaging.

FIG. 2B illustrates an exemplary stitched image of a target location in accordance with one or more embodiments of the present disclosure.

FIG. 3 illustrates images of a plurality of regions of interest of a target location taken via beam deflection in accordance with one or more embodiments of the present disclosure.

FIG. 4 illustrates a block diagram of a measurement sub-system, in accordance with one or more embodiments of the present disclosure

FIG. 5 illustrates flowcharts of steps of a method for generating a stitched image of a plurality of regions of interest of a target location, in accordance with one or more embodiments of the present disclosure

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to a system and method for focusing the electron scan during eBeam metrology to a single RoI of the target per scan, resulting in fewer electrons being used for metrology. Through focusing the eBeam to one RoI per scan, the Move Acquire Measure (MAM) times are increased (e.g., approximately 20%-60% MAM gain) and become more efficient, thereby reducing the Cost of Ownership (CoO) for customers and/or operators. In embodiments, the present disclosure includes three primary steps, (1) automatic RoI creation using design and recipe import; (2) RoI scanning during recipe run; and (3) stitching RoI scanned images to synthetic FoV-like image to calculate metrology values.

Furthermore, embodiments of the present disclosure provide for RoI scanning during a recipe run. Even further, the present disclosure provides for a complete range of imaging conditions of the SEM tool in terms of pixel size, acquisition time, RoI size and shapes, including device patterns, number of Rols, and number of stage moves between RoI (grabbed using only eBeam deflection).

Accordingly, through focusing the eBeam to the region of interest, approximately 60% less electrons may be used to image targets when compared to a conventional full FoV scan. Furthermore, as the RoI may be stitched to derive the final image, there are no changes required to the remaining portion of the imaging algorithm used in imaging the target and/or calculating metrology values. Similarly, through use of rule based polygonal dimensions and storing designs and rules as part of the recipe, scaling is improved as the recipe may be used for subsequent targets. Even further, embodiments of the present disclosure provide for a greater than 50% improvement in image acquisition time leading to commensurate gain in total metrology CoO.

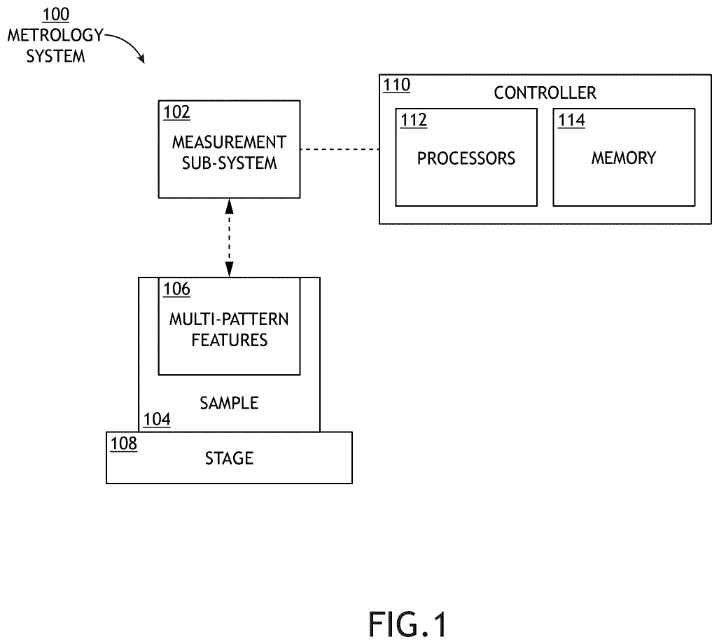

Referring now to the figures, FIG. 1 illustrates a block diagram of a metrology system 100, in accordance with one or more embodiments of the present disclosure.

In embodiments, the metrology system 100 includes a measurement sub-system 102 configured to measure a sample 104 having multi-pattern features 106 (e.g., features fabricated through a multi-patterning process such as, but not limited to, self-aligned double patterning (SAQP)).

The sample 104 may include multi-pattern features 106 generated using a multi-patterning process. In some cases, the multi-pattern features 106 may be, but are not required to be, located within a die region of the sample 104. The sample 104 may comprise various types of semiconductor structures or devices. For example, the sample 104 may include, but is not limited to, integrated circuits, memory devices (e.g., DRAM devices, or the like), logic devices, transistors, or other semiconductor structures fabricated using multi-patterning techniques. The sample 104 may include a substrate formed of a semiconductor or non-semiconductor material (e.g., a wafer, or the like). For example, a semiconductor or non-semiconductor material may include, but is not limited to, monocrystalline silicon, gallium arsenide, and indium phosphide. The sample 104 may further include one or more layers disposed on the substrate. For example, such layers may include, but are not limited to, a resist, a dielectric material, a conductive material, and/or a semiconductive material. Many different types of such layers are known in the art, and the term sample as used herein is intended to encompass a sample 104 on which all types of such layers may be formed. One or more layers formed on a sample 104 may be patterned or unpatterned. For example, a sample 104 may include a plurality of dies, each having repeatable patterned features. Formation and processing of such layers of material may ultimately result in completed devices. Many different types of devices may be formed on a sample 104, and the term sample as used herein is intended to encompass a sample 104 on which any type of device known in the art is being fabricated. The metrology system 100 and methods disclosed herein may be broadly suitable for any type of devices or components including, but not limited to, integrated circuit devices, automotive devices, camera sensors, or the like.

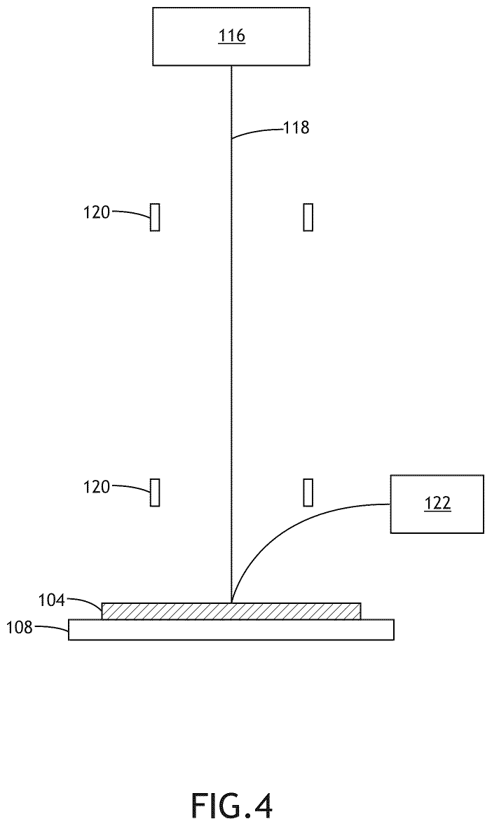

The measurement sub-system 102 may utilize various techniques to characterize the sample 104. In some cases, the measurement sub-system 102 may employ particle-beam based methods that direct a particle beam (e.g., an electron beam, an ion beam, a neutral-particle beam, or the like) towards the sample 104 and capture metrology data associated with particles and/or electromagnetic radiation from the sample 104. For example, a measurement sub-system 102 including a scanning electron microscope (SEM) is described in greater detail below with respect to FIG. 4. In some cases, the measurement sub-system 102 may employ optical methods that direct an optical beam (e.g., light) towards the sample 104 and capture metrology data associated with light reflected, scattered, and/or diffracted from the sample 104.

In embodiments, the metrology system 100 includes a stage 108 to secure and/or position the sample 104 with respect to the measurement sub-system 102. The stage 108 may include any number or type of actuators including, but not limited to, linear, rotational, or tip/tilt actuators to provide precise movement and alignment of the sample 104 in any number of degrees of freedom.

In embodiments, the metrology system 100 also includes a controller 110 including one or more processors 112 configured to execute program instructions stored on a memory 114 (e.g., memory medium). The controller 110 may be communicatively coupled with any components of the metrology system 100 including, but not limited to, the measurement sub-system 102 or the stage 108.

In embodiments, the metrology system 100 may be configured according to a metrology recipe that defines various aspects of the measurement process. The metrology recipe may specify operational parameters for the measurement sub-system 102, such as electron beam energy, beam current, scan speed, and detector settings when using a scanning electron microscope. The recipe may also define a sequence of measurement locations on the sample 104, including coordinates for anchor locations and subsequent measurement locations relative to those anchor points. In some cases, the metrology recipe may incorporate information from a design file that describes the layout and characteristics of multi-pattern features 106 on the sample 104, allowing for precise targeting of specific features or regions of interest.

The controller 110 may execute the metrology recipe to control the overall measurement and analysis process. This may include instructing the stage 108 to position the sample 104 at specified locations, configuring the measurement sub-system 102 according to defined parameters, and performing a series of image capture and analysis steps. The metrology recipe may define how the controller 110 should process measurement data, such as specifying algorithms for aligning captured images with design files, correlating features to specific steps of the multi-patterning process, and calculating metrology measurements. Additionally, the recipe may outline how to generate spatial maps or other visualizations of measurement results, and may include criteria for identifying process-specific errors or variations across the sample 104.

As set forth herein, embodiments of the present disclosure are directed to systems and methods for focusing an electron scan to one or more regions of interest, capturing images of the regions of interest, and then stitching the plurality of images together, providing for a synthetically stitched image that is equivalent to a traditional field of view image.

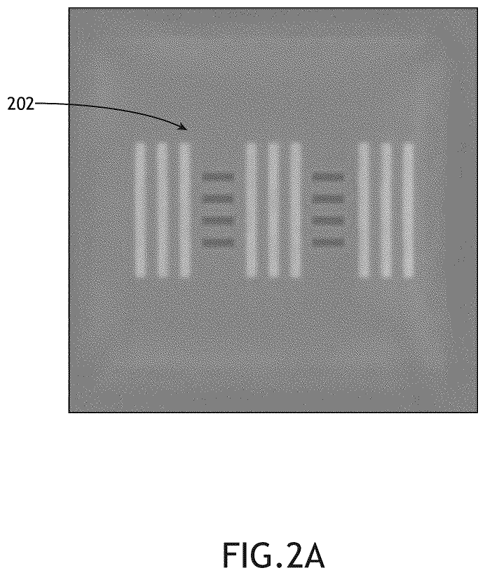

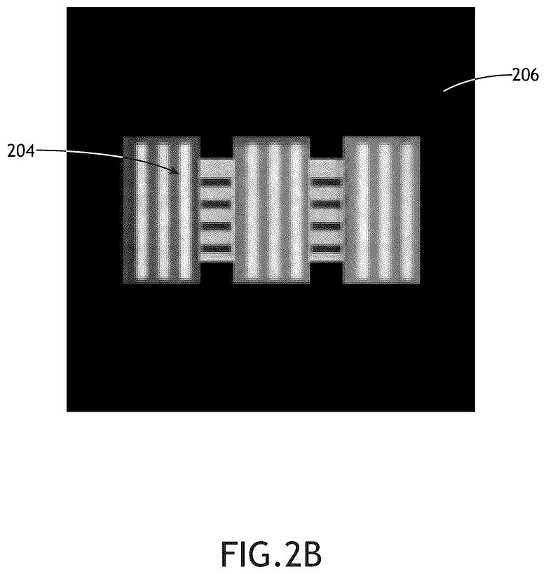

FIGS. 2A and 2B depict exemplary final image results of a target (e.g., substrate or wafer), with FIG. 2A depicting a conventional full image FoV 202 and FIG. 2B depicting a synthetically stitched image 204 from multiple scanned RoIs utilizing the teachings of the present disclosure. As depicted in FIG. 2A, under conventional or traditional methods of obtaining a full image FoV via an SEM scan, there is a lack of clear distinction across the various RoIs in the full image FoV 202. Furthermore, as the entire FoV is captured, there is inefficient usage of electrons, as the electrons are directed to the entire area corresponding to the FoV.

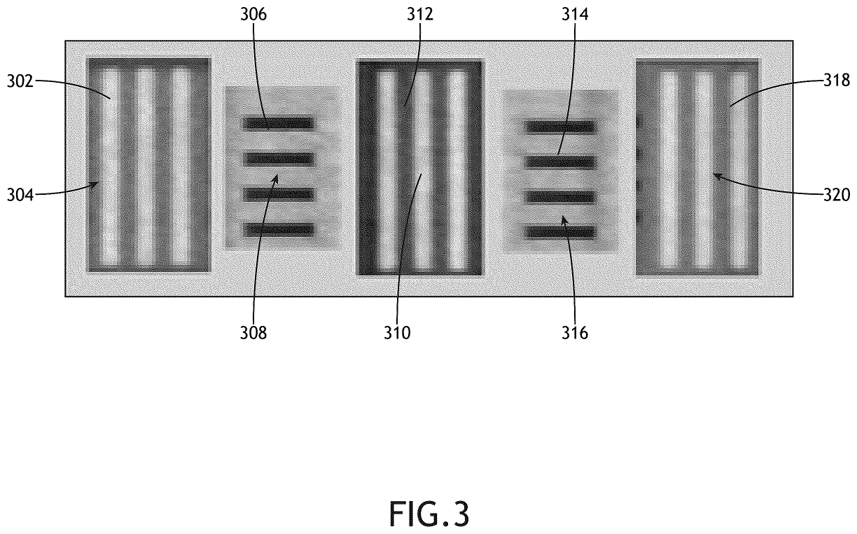

As depicted in FIG. 2B, an exemplary image of a synthetically stitched image 204 from multiple scanned RoIs is depicted. For example, the synthetically stitched image 204 may be created through the stitching of the first image 302, the second image 306, the third image 310, the fourth image 314 and the fifth image 318 as described below with respect to FIG. 3. As further depicted and as further described herein, the respective images may be stitched to a generated black image 206 using previously selected or determined locations. As described in greater detail herein, the synthetically stitched image 204 may be stitched using one or more algorithms, such that the location of the images corresponding to the RoIs during stitching are pre-determined. In this regard, the synthetically stitched image 204 may be processed and generated in a time and/or cost-efficient manner. Furthermore, the synthetically stitched image 204 may be scalable and/or reusable, such that subsequent synthetically stitched images may be generated in subsequent imaging.

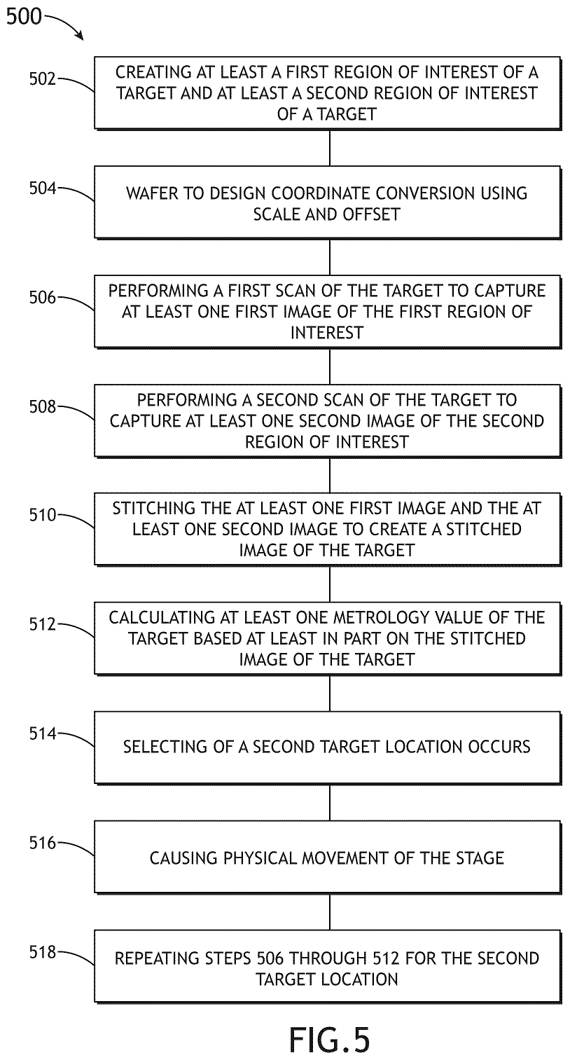

FIG. 3 depicts various exemplary images of a plurality of RoIs taken by an SEM tool with a single stage move (i.e., taken using only beam deflection). As depicted in FIG. 3, embodiments of the present disclosure provide for the capturing of a first image 302 corresponding to a first region of interest 304, a second image 306 corresponding to a second region of interest 308, a third image 310 corresponding to a third region of interest 312, a fourth image 314 corresponding to a fourth region of interest 316, and a fifth image 318 corresponding to a fifth region of interest 320. For example, each of the first region of interest 304, the second region of interest 308, the third region of interest 312, and the fourth region of interest 316 may be previously created auto-RoIs based on the previously defined rules. As described herein, the eBeam (or other illumination beam or particle beam) may be deflected to each region of interest such that the corresponding image is of the respective RoI only. As further described herein, through the deflecting of the eBeam, the plurality of images may be captured without physical movement of the stage. It should be noted that while the embodiment depicted in FIG. 3 depicts five images corresponding to five Rols, any number of RoIs and corresponding images may be selected during imaging. Furthermore, as described in greater detail with respect to FIG. 5, the present disclosure provides for the creation of automatically created or generated Rols. Accordingly, each of the RoIs depicted in FIG. 3 may correspond to an automatically created or generated RoI as described herein.

Referring now to FIG. 4, additional aspects of the measurement sub-system 102 are described in greater detail, in accordance with one or more embodiments of the present disclosure. In a general sense, the measurement sub-system 102 may include any components suitable for generating images of a sample 104. For example, the measurement sub-system 102 may include an optical sub-system, a particle-beam sub-system, or an x-ray sub-system.

FIG. 4 illustrates a block diagram of a measurement sub-system 102, in accordance with one or more embodiments of the present disclosure. For example, FIG. 4 may depict a non-limiting example of a SEM measurement sub-system 102.

In embodiments, the measurement sub-system 102 includes a particle source 116 to generate a particle beam 118. The particle source 116 may include any particle source known in the art suitable for generating a particle beam 118. For example, the particle source 116 may include, but is not limited to, an electron gun or an ion gun. In another embodiment, the particle source 116 is configured to provide a particle beam with a tunable energy. For example, a particle source 116 including an electron source may, but is not limited to, provide an accelerating voltage in the range of 0.1 kV to 30 kV. As another example, a particle source 116 including an ion source may, but is not required to, provide an ion beam with an energy in the range of 1 to 50 keV.

In another embodiment, the particle control elements 120 includes one or more particle focusing elements. For example, the one or more particle focusing elements may include, but are not limited to, a single particle focusing element or one or more particle focusing elements forming a compound system. In another embodiment, the one or more particle focusing elements include an objective lens configured to direct the particle beam 118 to the sample 104. Further, the one or more particle focusing elements may include any type of electron lenses known in the art including, but not limited to, electrostatic, magnetic, uni-potential, or double-potential lenses.

In another embodiment, the measurement sub-system 102 includes one or more particle detectors 122 to image or otherwise detect particles emanating from the sample 104. In one embodiment, the particle detector 122 includes an electron collector (e.g., a secondary electron collector, a backscattered electron detector, or the like). In another embodiment, the particle detector 122 includes a photon detector (e.g., a photodetector, an x-ray detector, a scintillating element coupled to photomultiplier tube (PMT) detector, or the like) for detecting electrons and/or photons from the sample surface.

Turning now to FIG. 5, an exemplary method of use of the present disclosure is depicted generally through method 500. In embodiments, the method 500 may be utilized in calculating one or more metrology values for a target including for example, measuring overlay or CD errors, by focusing an eBeam (or other type of particle beam or illumination beam) to one region of interest per scan, such that a single image of a particular RoI is obtained. The method 500 further includes stitching together a plurality of images of a plurality of Rols, such that a synthetically stitched image approximate to a FoV may be obtained.

In embodiments, step 502 includes creating at least a first region of interest of a target and at least a second region of interest of a target (e.g., sample 104). In embodiments, each of the first region of interest and the second region of interest may be defined by one or more previously established rules for polygonal dimensions. For example, in step 502, RoIs for the target may be automatically created using one or more design targets in Open Artwork System Interchange Standard (OASIS) file format. However, any known and suitable file format may be utilized, including any format that may store polygonal dimensions in a binary format. End user may provide the polygonal dimensions, including for example, minimum space, minimum width, measurement directions, polygonal shapes, among other polynomial dimensions, via Electronic Design Automation (EDA) tools. Furthermore, the design polygons may be in a format that provides for later manipulation, including for example standard verification rule format (SVRF). With the user provided polygonal dimensions, the RoIs may be automatically created, with one or more RoIs being generated that correspond to the user provided polygonal dimensions. In embodiments, the polygonal dimensions may be manipulated or changed using scripting languages such as Standard Verification Rule Format (SVRF), such that the polygonal dimensions may be updated or refined as desired.

As provided in step 502, since RoIs are automatically derived from previously established rules, subsequent automatically created RoIs may be utilized across different layers of a single target device and/or across a plurality of different targets having different designs, patterns, shapes, sizes, etc. For example, during step 502, each of the first region of interest and the second region of interest may be based or defined by one or more previously established rules for polygon dimensions. Accordingly, a range of imaging conditions of the SEM tool may be controlled or selected through the ruled-based Rols. For example, imaging conditions such as pixel size, acquisition time, ROI size, shapes including device patterns, and/or number of RoIs per target. Accordingly, and in embodiments, through the creation of RoIs via previously established rules, end user variability and/or error sources may be removed during RoI creation. Furthermore, through rule-based Rols, scalability and re-usability of scripts for RoI generation is possible, providing for consistent RoI generation across multiple layers and/or products.

In alternative and/or further embodiments, in the event that OASIS, or equivalent, format files are not available, rasterized images of the design of the target may also be utilized for automated RoI generation or creation. For example, in embodiments, a conversion of binary files to polygon data may be performed using a contour extraction approach.

In embodiments, after the creation of the rule-based RoI(s), the created ruled-based RoI(s) may be imported into a recipe, formula, calibration chip, or other start up condition storage associated with an illumination system/metrology tool.

In embodiments, an optional or further step 504 includes a wafer to design coordinate conversion using scale and offset. In embodiments, the wafer to design coordinate conversion may be conducted during the metrology recipe set up and/or simultaneously with step 502 as provided above. In embodiments, performing a wafer to design coordinate conversion in addition to RoI creation as outlined in step 502 may reduce stage navigation of the metrology tool while traversing to measurement targets. For example, through automating the process by creating rule-based polygon dimensions, user variability and/or user induced accuracy errors in marking the center of a measurement target that contains the RoI may be removed or reduced. Furthermore, through converting the actual pattern of the wafer to a design coordinate, increased accuracy during traversing to the specified measurement targets may be achieved. In embodiments, the wafer to design coordinate conversion using scale and offset may be conducted during the metrology recipe setup.

At step 506, performing a first scan of the target to capture at least one first image of the first region of interest is performed. In embodiments, step 506 is completed at least after step 502 has been performed and may be completed during the job run. For example, during the job run, the eBeam (or other illumination beam or particle beam) may be directed to the target location of the target (e.g., sample 104). In embodiments, the stage housing the target may be moved to a center of the target location prior to performing the first scan. In embodiments, the target location may be offset of the first region of interest from the center of the target location. For example, the width and/or height of the first region of interest may be retrieved from the recipe and using the recipe, the stage/beam may be initially instructed to be directed to the center of the target location. After centering, the eBeam may then be deflected to the first region of interest, with the deflections being based on the offset values of the ruled-based polygon dimensions associated with the first region of interest to obtain at least one first image of the first region of interest.

At step 508, performing a second scan of the target to capture at least one second image of the second region of interest is performed. In embodiments, step 508 may be largely identical to step 506 and may be performed subsequently or near simultaneously with step 506. For example, during step 508 the eBeam may be deflected based at least in part on the offset values associated with the second region of interest such that at least one image of the second region of interest is captured.

Accordingly, in embodiments, steps 506 and step 508 may be utilized to capture at least one image of two or more regions of interest within the same measurement target without moving the stage and/or the illumination source. Rather, the eBeam (or other illumination beam or particle beam) may be deflected towards the first region of interest and the second region of interest to capture images of the two regions on interest. Furthermore, through the rule-based regions of interest, a range of imaging condition of the metrology tool may be controlled, including for example, pixel size, acquisition time, region of interest size, region of interest shape, number of regions of interest selected for imaging, etc.

At step 510, stitching the at least one first image and the at least one second image to create a stitched image of the target is performed. As described above with respect to steps 506 and 508, one or more images of one or more regions of interest of the target may be captured without moving the stage that the target is located on. Through stitching of the multiple captured images, a synthetic stitched image may be created. For example, and in embodiments, during steps 506 and 508 the deflection of the eBeam to the first region of interest and the second region of interest may be utilized to capture images that are smaller in size than the field of view of the target, but are otherwise higher fidelity, accurate, and utilize fewer electrons to capture. In step 510, the multiple images may be synthetically stitched to form a synthetically stitched image that is equivalent or near equivalent in size to the filed of view. For example, the synthetically stitched image may include a generated plain black image that is created in size of the target FoV. Following generation of the plain black image, the captured images of the various regions of interest are stitched to the plain black image using the offset values form the center of the image, which may be known and stored in the recipe. Accordingly, because the offset values of the created RoI are previously known, the location of the captured images on the plain black image, and therefore, the final synthetically stitched image may be known prior to stitching, leading to faster and/or reliable results.

At step 512, calculating at least one metrology value of the target based at least in part on the stitched image of the target occurs. For example, the synthetic stitched image may be utilized by the controller 110 or otherwise utilized by a computing system for calculating one or more metrology values that are known in the art. In particular, as identified above, current metrology systems and algorithms support only one image per target location. Through the synthetically stitched image however, a single resultant image may be utilized in the calculations, with the single synthetically stitched image being reused and avoiding any re-writes, thereby resulting in more efficient calculations and determinations of the one or more metrology values. In embodiments, step 512 may further including sending or feeding the synthetically stitched image to an algorithm pipeline for calculating the at least one metrology value of the target.

At an optional or further step 514, selecting of a second target location occurs. As described herein, images of multiple RoIs per target location may be achieved through eBeam deflection rather than through physical movement of the stage. In embodiments, following capturing of the two or more images at a first target location, a second target location may be selected for imaging. In embodiments, the second target location may be a second layer of the previously imaged target. In embodiments, the second target location may be a subsequent or different target (i.e., a second sample 104).

At step 516, causing physical movement of the stage occurs. In embodiments, physical movement of the stage occurs to position the substrate for imaging at the second target location. For example, after generating the synthetically stitched image of the first target, physical movement of the stage may occur that moves the stage to a center of the second target layer.

At step 518, any of the steps 506-412 may be repeated for the second target location.

Referring again to FIG. 1, the controller 110 may include one or more processors 112 configured to execute program instructions. The program instructions may be maintained on memory 114 or a memory medium. The one or more processors 112 of the controller 110 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 112 may include any device configured to execute algorithms and/or instructions (e.g., program instructions stored in memory). In some embodiments, the one or more processors 112 may be embodied as a desktop computer, mainframe computer system, workstation, image computer, parallel processor, networked computer, or any other computer system configured to execute a program configured to operate or operate in conjunction with the system, as described throughout the present disclosure.

The memory 114 may include any storage medium known in the art suitable for storing program instructions executable by the associated one or more processors 112. For example, the memory 114 may include a non-transitory memory medium. By way of another example, the memory 114 may include, but is not limited to, a read-only memory (ROM), a random-access memory (RAM), a magnetic or optical memory device (e.g., disk), a magnetic tape, a solid-state drive and the like. In some cases, the memory 114 may be housed in a common controller housing with the one or more processors 112. In some embodiments, the memory 114 may be located remotely with respect to the physical location of the one or more processors 112 and controller 110. For instance, the one or more processors 112 of the controller 110 may access a remote memory (e.g., server), accessible through a network (e.g., internet, intranet and the like).

The controller 110 may be communicatively coupled with any component of the metrology system 100. In some cases, the controller 110 may directly or indirectly (e.g., via control signals) perform any steps described in the present disclosure. The controller 110 may execute program instructions to control the operation of the measurement sub-system 102, process measurement data, and perform various analysis tasks related to the multi-pattern features 106 on the sample 104. For example, the controller 110 may receive measurement images from the measurement sub-system 102, modify design files to correlate designed features to particular steps of a multi-patterning process, align images with design files, or generate measurement data correlated to particular steps of a multi-patterning process.

In embodiments, the controller 110 may be configured to generate correctables that are utilized to control various process tools in semiconductor manufacturing such as, but not limited to, lithography tools (e.g., a scanner, a stepper, or the like), etching tools, or polishing tools. In some cases, the correctables may be applied using of feedback and/or feed-forward techniques to optimize process control across multiple time scales and manufacturing steps. In a feedback configuration, the overlay measurements from a completed wafer or lot may be used to adjust process parameters for future wafers or lots, helping to compensate for systematic errors or drifts in the manufacturing process. Alternatively, in a feed-forward configuration, the overlay measurements from initial layers of a wafer may be used to adjust process parameters for subsequent layers on the same wafer, potentially allowing for real-time corrections to be applied during the manufacturing process.

It is further contemplated that each of the embodiments of the method described above may include any other step(s) of any other method(s) described herein. In addition, each of the embodiments of the method described above may be performed by any of the systems described herein.

Any of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A system for focusing one or more illumination beams to one or more regions of interest comprising:
a controller including one or more processors configured to execute program instructions stored in a memory device, wherein the program instructions are configured to cause the one or more processors to focus an illumination beam to a region of interest by:
creating at least a first region of interest of a target and at least a second region of interest of the target, wherein each of the first region of the target and the second region of interest defined by one or more previously established rules for polygonal dimensions;
performing a first scan of the target to capture at least one first image of the first region of interest;
performing a second scan of the target to capture at least one second image of the second region of interest; and
stitching the at least one first image and the at least one second image to create a stitched image of the target.

2. The system of claim 1, wherein the program instructions are further configured to cause the one or more processors to:
calculate at least one metrology value of the target based at least in part on the stitched image of the target.

3. The system of claim 1, wherein the program instructions are further configured to cause the one or more processors to:
retrieve the one or more previously established rules for polygonal dimensions from a recipe.

4. The system of claim 3, wherein the program instructions are further configured to cause the one or more processors to:
select a first target layer, wherein the target is located on a location of the first target layer.

5. The system of claim 4, wherein the first region of interest and the second region of interest are located on the first target layer.

6. The system of claim 1, wherein each of the first region of interest and the second region of interest are created using design targets in an Open Artwork System Interchange Standard (OASIS) file format, and
wherein the design targets are stored in a binary format.

7. The system of claim 1, wherein the polygonal dimensions include at least one of a minimum space or a minimum width.

8. The system of claim 1, wherein each of the first region of interest and the second region of interest are created from one or more rasterized images generated from binary to polygon data conversion.

9. The system of claim 1, wherein the program instructions are further configured to cause the one or more processors to:
during a metrology recipe setup, perform a wafer to design coordinate conversion using scale and offset.

10. The system of claim 1, wherein the program instructions are further configured to cause the one or more processors to:
generate a black image approximate to a size of a field of view of the target; and
wherein the stitched image is stitched to the generated black image.

11. The system of claim 10, wherein the stitching is completed using offset values associated with each of the first region of interest and the second region of interest from a center of the black image.

12. The system of claim 11, wherein the center of the black image is stored in a recipe.

13. The system of claim 2, wherein the program instructions are further configured to cause the one or more processors to:
send the stitched image to an algorithm pipeline for calculating the at least one metrology value of the target.

14. The system of claim 1, wherein the first region of interest comprises a dimension, size, or shape that is different that a dimension, size, or shape of the second region of interest.

15. The system of claim 1, wherein the first image and second image are obtained during a run job, and
wherein prior to obtaining the first and second image during the run job, a stage housing the target is move to a center of a target location.

16. The system of claim 15, wherein the program instructions are further configured to cause the one or more processors to:
deflect one or more illumination beams to each of the first region of interest and the second region of interest without causing the stage to be moved during the deflecting.

17. The system of claim 16, wherein the program instructions are further configured to cause the one or more processors to:
select a second target layer, and
upon selection of the second target layer, performing:
creating at least a first region of interest of the target at the second target layer and at least a second region of interest of the target at the second target layer, wherein each of the first region of the target and the second region of interest defined by one or more previously established rules for polygonal dimensions;
performing a first scan of the target at the second target layer to capture at least one first image of the first region of interest;
performing a second scan of the target at the second target layer to capture at least one second image of the second region of interest; and
stitching the at least one first image and the at least one second image to create a stitched image of the target at the second target layer.

18. The system of claim 17, wherein the program instructions are further configured to cause the one or more processors to:
upon generating a synthetically stitched image of the first target, move the stage to a center of the second target layer.

19. A system for focusing an electron beam to two or more regions of interest, the system comprising:
an illumination source configured to generate one or more illumination beams;
a set of optical elements configured to direct the one or more illumination beams from the illumination source to a surface of a substrate; and
one or more controllers including one or more processors configured to execute program instructions causing the one or more processors to:
a controller including one or more processors configured to execute program instructions stored in a memory device, wherein the program instructions are configured to cause the one or more processors to focus an electron scan to a plurality of regions of interest by:
creating at least a first region of interest of a target and at least a second region of interest of the target, each of the first region of the target and the second region of interest defined by one or more previously established rules for polygonal dimensions;
performing a first scan of the target to capture at least one first image of the first region of interest;
performing a second scan of the target to capture at least one second image of the second region of interest;
stitching the at least one first image and the at least one second image to create a stitched image of the target; and
calculating at least one metrology value of the target based at least in part on the stitched image of the target.

20. A method for focusing one or more illumination beams to one or more regions of interest on a target comprising:
creating at least a first region of interest of a target and at least a second region of interest of the target, each of the first region of the target and the second region of interest defined by one or more previously established rules for polygonal dimensions;
performing a first scan of the target to capture at least one first image of the first region of interest;
performing a second scan of the target to capture at least one second image of the second region of interest;
stitching the at least one first image and the at least one second image to create a stitched image of the target; and
calculating at least one metrology value of the target based at least in part on the stitched image of the target.
